(19) United States
(12) Patent Application Publication
(10) Pub. No.: US 2007/0267649 A1
(43) Pub. Date: Nov. 22, 2007

(54) SEMICONDUCTOR LASER DEVICE

(75) Inventors: Koichi Matsushita, Kanagawa-ken (JP); Hironobu Miyasaka, Fukuoka-ken (JP); Masanori Yamada, Kanagawa-ken (JP); Kazuya Tsunoda, Kanagawa-ken (JP); Reiji Ono, Kanagawa-ken (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/751,707

(22) Filed: May 22, 2007

(30) Foreign Application Priority Data
May 22, 2006 (JP) 2006-141696
Feb. 5, 2007 (JP) 2007-25976

(51) Int. Cl. H01L 33/00; H01L 31/113

(52) U.S. Cl. 257/99; 257/79; 257/98; 257/290

(57) ABSTRACT

In one aspect, a semiconductor laser device may include a supporting member, a semiconductor laser element provided over the supporting member, and configured to emit a laser from a front surface and monitoring laser from a rear surface, and a photo receiving element provided over the supporting member, and configured to receive the monitoring laser from the semiconductor laser element at a photo receiving region, the photo receiving region provided on a side surface of the photo receiving element, wherein the side surface of the photo receiving element has a smaller area than an area of a bottom surface of the photo receiving element.

### CROSS REFERENCE TO RELATED APPLICATION

This application is based upon and claims the benefit of priority from Japanese Patent Application No. 2006-141696, filed on May 22, 2006, and from Japanese Patent Application No. 2007-25976, filed on Feb. 5, 2007, the entire contents of which are incorporated herein by reference.

### BACKGROUND

In a conventional semiconductor device, a semiconductor laser element and a photo receiving element are provided. The photo receiving element receives a monitoring laser from the semiconductor laser element. In such case, the monitoring laser is reflected by the inner surface of an enclosure of the semiconductor laser device and irradiated to a photo receiving region of the photo receiving element which faces upward. In the conventional semiconductor laser device, it may be difficult to be provided in a small package.

In the conventional photo receiving element, the photo receiving region is provided on a top surface of the semiconductor substrate. So when the monitoring laser is directly irradiated into the photo receiving region without reflecting by the inner surface of the enclosure, the photo receiving element is provided as its side surface faces down. In such case, mounting the photo receiving element on a lead frame is difficult, since the area in contact with the lead frame is smaller than the surface, which faces the semiconductor laser element.

### SUMMARY

Aspects of the invention relate to an improved semiconductor light emitting device.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross sectional view of a semiconductor laser device in accordance with a first embodiment.

FIG. 2 is a perspective view of the semiconductor laser device in accordance with the first embodiment.

FIG. 3A is a plane view of a photo receiving element in accordance with the first embodiment. FIG. 3B is a cross sectional view cut along A-A line in FIG. 3A of a photo receiving element in accordance with the first embodiment.

FIGS. 4A-4D are cross sectional views showing a manufacturing process of the photo receiving element in accordance with the first embodiment.

FIGS. 5A-5D are cross sectional views showing a manufacturing process of the photo receiving element in accordance with the first embodiment.

FIGS. 6A-6C are cross sectional views showing a manufacturing process of the semiconductor laser device in accordance with the first embodiment.

FIG. 7 is a cross sectional view of a semiconductor laser device in accordance with a second embodiment.

FIG. 8 is a cross sectional view of a photo receiving element in accordance with the second embodiment.

FIG. 9A is a plane view of a semiconductor laser device in accordance with the third embodiment. FIG. 9B is a cross sectional view of the semiconductor laser device in accordance with the third embodiment.

FIG. 10A is a perspective view of a photo receiving element in accordance with the third embodiment. FIG. 10B is a cross sectional view of the photo receiving element in accordance with the third embodiment.

FIG. 11A is a timing of the semiconductor laser device in accordance with the third embodiment. FIG. 11B is a timing of the semiconductor laser device in accordance with a comparative example.

FIG. 12 is a plane view of a semiconductor laser device in accordance with a fourth embodiment.

FIG. 13A is a perspective view of a semiconductor laser element in accordance with a modification of the fourth embodiment. FIG. 13B is a perspective view of a photo receiving element in accordance with the modification of the fourth embodiment.

FIG. 14A is a perspective view of a photo receiving element in accordance with a fifth embodiment. FIG. 14B is a cross sectional view of the photo receiving element in accordance with the fifth embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### General Overview

In one aspect of the present invention, a supporting member, a semiconductor laser element provided over the supporting member, and configured to emit a laser from a front surface and monitoring laser from a rear surface, and a photo receiving element provided over the supporting member, and configured to receive the monitoring laser from the semiconductor laser element at a photo receiving region, the photo receiving region provided on a side surface of the photo receiving element, wherein the side surface of the photo receiving element has a smaller area than an area of a bottom surface of the photo receiving element.

In another aspect of the invention, a semiconductor laser device may include a supporting member, a semiconductor laser element provided over the supporting member, and configured to emit a plurality of lasers from a front surface and a plurality of monitoring lasers from a rear surface, and a photo receiving element provided over the supporting member, and configured to receive the plurality of monitoring lasers from the semiconductor laser element at a plurality of photo receiving regions respectively, each of the plurality of photo receiving regions provided on a side surface of the photo receiving element, wherein the side surface of the photo receiving element has a smaller area than an area of a bottom surface of the photo receiving element, and the photo receiving element is spaced from the semiconductor laser element so that the plurality of the monitoring lasers does not cross each other.

In another aspect of the invention, a semiconductor laser device may include a supporting member, a plurality of semiconductor laser elements provided over the supporting member, each semiconductor laser element configured to emit a laser from a front surface and a monitoring laser from a rear surface, respectively, and a photo receiving element provided over the supporting member, and configured to receive the plurality of monitoring lasers from the plurality of semiconductor laser elements at a plurality of photo receiving regions respectively, the plurality of photo receiving regions provided on a side surface of the photo receiving element, wherein the side surface of the photo receiving element has a smaller area than an area of a bottom surface of the photo receiving element, and the photo receiving element is spaced from the plurality of the semiconductor laser elements so that the plurality of the monitoring lasers does not cross each other.

### First embodiment

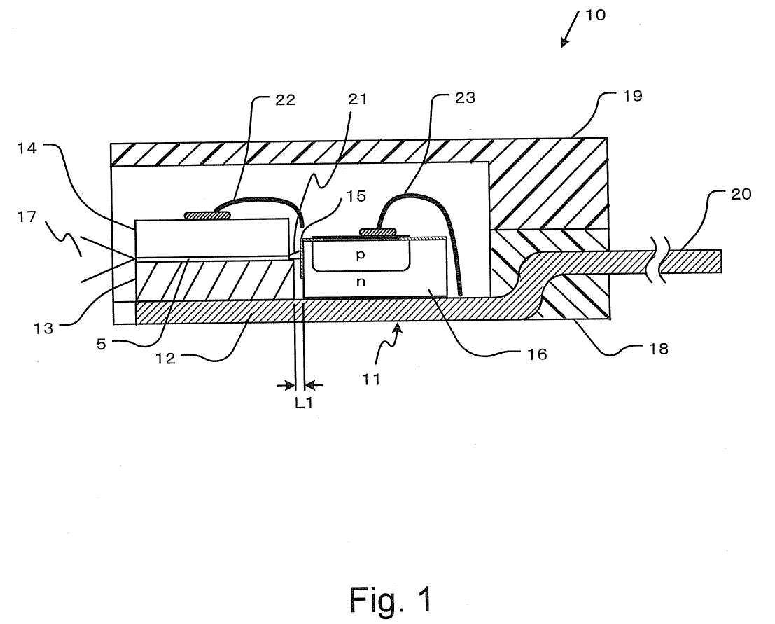

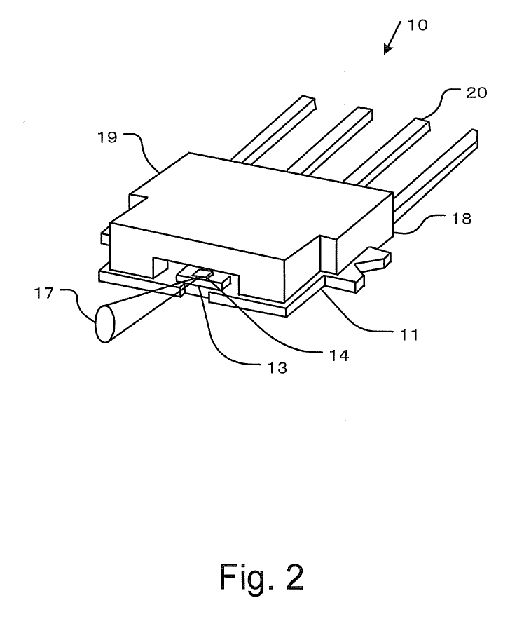

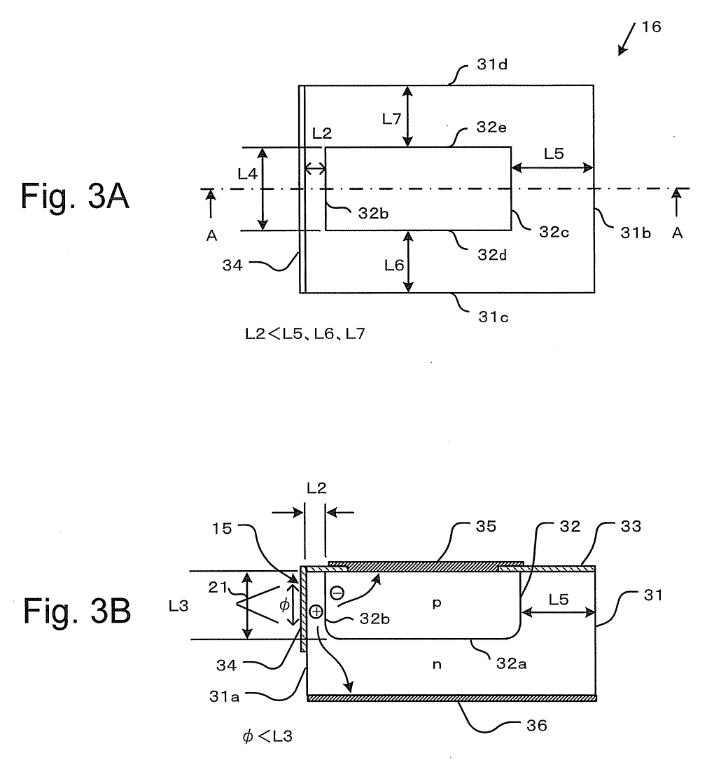

A first embodiment is explained with reference to FIGS. 1-6. A structure of a semiconductor laser 10 will be explained with reference to FIGS. 1-3. FIG. 1 is a cross sectional view of a semiconductor laser device 10 in accordance with a first embodiment. FIG. 2 is a perspective view of the semiconductor laser device 10 in accordance with the first embodiment. FIG. 3A is a plane view of a photo receiving element 16 in accordance with the first embodiment. FIG. 3B is a cross sectional view cut away along A-A line in FIG. 3A of a photo receiving element 16 in accordance with the first embodiment.

As shown in FIGS. 1 and 2, in the semiconductor laser device 10, a lead frame (supporting member) 11, a submount 13, a semiconductor laser element 14, a photo receiving element 16, an enclosure 18 and a cap portion 19 are provided.

The submount 13 is mounted on a mount bed 12 of the lead frame 11. The semiconductor laser element 14 is mounted on the submount 13 such that the front side (laser emitting side) of the semiconductor laser element 14 faces an opening of a region enclosed by the lead frame 11, the enclosure 18 and the cap portion 19.

The photo receiving element 16 is provided on the mount bed 12. The photo receiving element 16 is provided behind the semiconductor laser element 14, and configured to receive a monitoring laser 21 from the semiconductor laser element 14. A photo receiving region 15 of the photo receiving element 16 is provided on the side surface of the photo receiving element 16.

The semiconductor laser element 14 is electrically connected to the lead frame 11 via a wiring 22. The photo receiving element 16 is electrically connected to the lead frame 11 via a wiring 23.

As shown in FIG. 2, the lead frame 11 is enclosed by the enclosure 18. The cap 19 is provided on the enclosure 18.

A lead pin 20, which is one edge of the lead frame 11, is extended to outside from the enclosure 18.

The lead frame 11 may be made of Au plated Fe—Ni alloy. The submount 13 may be insulative material, and have preferably high heat conductivity. The submount 13 may be AlN, SiC, ceramics or the like. The submount 13 may function as a heat sink, which release a heat from the semiconductor laser element 14.

The semiconductor laser element 14 may be an edge emitter type semiconductor laser element. The semiconductor laser element 14 may be an InGaAlP based semiconductor laser, which emits red laser. The photo receiving element 16 may be a silicon photo diode.

A laser beam from the semiconductor laser element 14 may be an elliptic with its long axis being identical to vertical direction, in which the vertical divergence angle is about 20-40 degree and the lateral divergence angle is about 5-20 degree.

It is preferable that the distance L1, which is a distance from the semiconductor laser element 14 to the photo receiving element 16, is as short as possible. In case the distance L1 is shorter, the photo receiving region 15 is capable of being smaller. For example, the distance L1 may be about 50 micrometers.

The upper edge of the beam of the monitoring laser 21 irradiated on the surface of the photo receiving element 16 is provided in the photo receiving region 15. The lower edge of the beam of the monitoring laser 21 irradiated on the surface of the photo receiving element 16 is provided in the photo receiving region 15.

A height from the supporting member 11 to an active layer 5 of the semiconductor laser elements 14 is no less than a height from the supporting member 11 to a bottom of the photo receiving region 15 of the photo receiving element 16 and no more than a height from the supporting member 11 to a top of the photo receiving region 15 of the photo receiving element 16. The active layer 5 is a portion which a laser is emitted from.

Next, the photo receiving element 16 in the semiconductor laser device 10 will be explained with reference to FIGS. 3A-3B.

FIG. 3A is a plane view of the photo receiving element 16 in accordance with the first embodiment. FIG. 3B is a cross sectional view cut along A-A line in FIG. 3A of the photo receiving element in accordance with the first embodiment.

In the photo receiving element 16, a P type diffusion layer 32, which has about 1E18 cm⁻³ in the impurity concentration, is provided in an N type Si substrate 31, which has about 1E17 cm⁻³ in the impurity concentration and has about 150 micrometers in the thickness. The P type diffusion layer 32 is provided near the front side 31a (left in FIGS. 3A and 3B)of the photo receiving element 16.

The photo receiving region 15 is larger than the irradiated laser beam φ on the photo receiving element 16. The distance L3, which is from the top surface of the photo receiving element 16 to the lower edge 32a of the P type diffusion layer 32, is greater than the vertical length of the irradiated laser beam φ. The distance L4, which is the width of the P type diffusion layer 32 in the plane view as FIG. 3A, is larger than the lateral length of the irradiated laser beam φ.

As shown in FIG. 3B, the distance L2, which is from the front side 31a of the photo receiving element 16 to the front edge 32b of the P type diffusion layer 32, is less than the distance L5, which is from the rear side 31b (right in FIGS. 3A and 3B) of the photo receiving element 16 to the rear edge 32c of the P type diffusion layer 32. The distance L2 is less than the distance L6 which is from the side edge 32d to the side surface 31c of the photo receiving element 16. The distance L2 is less than the distance L7 which is from the side edge 32e to the side surface 31d of the photo receiving element 16. The distances L6 and L7 may be the same.

A protective layer 33, such as SiO₂, may be provided on the top surface of the Si substrate 31 and the P type diffusion layer 32. An anti reflection film 34, such as SiO₂, is provided on the front surface 31a of the photo receiving element 16.

The thickness of the anti reflection film 34 is (2m+1)λ/(4n). λ is the wavelength of the monitoring laser 21. n is the refraction index of the material of the anti reflection film 34. m is zero or natural number.

A P side electrode 35 is provided on the P type diffusion layer 32. An N side electrode 36 is provided on the bottom surface of the Si substrate 31.

The photo receiving element 16 having the photo receiving region in its front side surface 31a is obtained.

When the monitoring laser 21 reaches the PN junction 32b, carriers (electron, hole) are generated. The carriers move to the P side electrode 35 and the N side electrode 36, respectively. So optical current is generated.

The distance L2 may be greater than the thickness of a depletion layer of the PN junction 32b, and may be provided such that the absorption in the Si substrate is negligible. So the distance may be preferably about 5-10 micrometers.

In case the distance L1 is 50 micrometers, the lateral length of the irradiated laser beam φ is about 20 micrometers and the vertical length of the irradiated laser beam φ is about 40 micrometers. So the distance L3 may be no less than 40 micrometers and the distance L4 may be no less than 20 micrometers.

A scattering light on top surface of the photo receiving element 16 is not entered into the Si substrate 31, since the P side electrode 35 is provided on the top surface of the photo receiving element 16. So the scattering light is hardly reached the PN junction 32b. So carriers for noise may be reduced.

A scattering light from the side surfaces 31b, 31c and 31d, on which the photo receiving region 15 are not provided, is absorbed in the Si substrate 31, since the distances L5, L6, and L7 are greater than the distance L2, respectively. So the scattering light is hardly reached the PN junction 32b. So carriers for noise may be reduced.

As shown in FIGS. 3A and 3B, the side surface of the photo receiving element 16 has a smaller area than a bottom surface of the photo receiving element 16. So it may be easy to mount on the lead frame 11.

In a conventional photo receiving element used for monitoring laser in the semiconductor laser device, a photo receiving surface is provided on a top surface of the conventional photo receiving element. In other words, the receiving region is provided parallel to the bottom surface of the semiconductor substrate of the photo receiving element. So the conventional photo receiving element is mounted on a lead frame as the side surface of the conventional photo receiving element faces the lead frame. Thus it is hard to be mounted on the lead frame accurately, since the side surface of the photo receiving element has smaller area than the bottom surface of the photo receiving element and the mounted photo receiving element is unstable.

On the contrary with the conventional photo receiving element, the photo receiving element 16 is mounted on the lead frame 11 stably. This may be that the bottom surface of the photo receiving element 16 has a smaller area than the area of the front side surface of the photo receiving element 16.

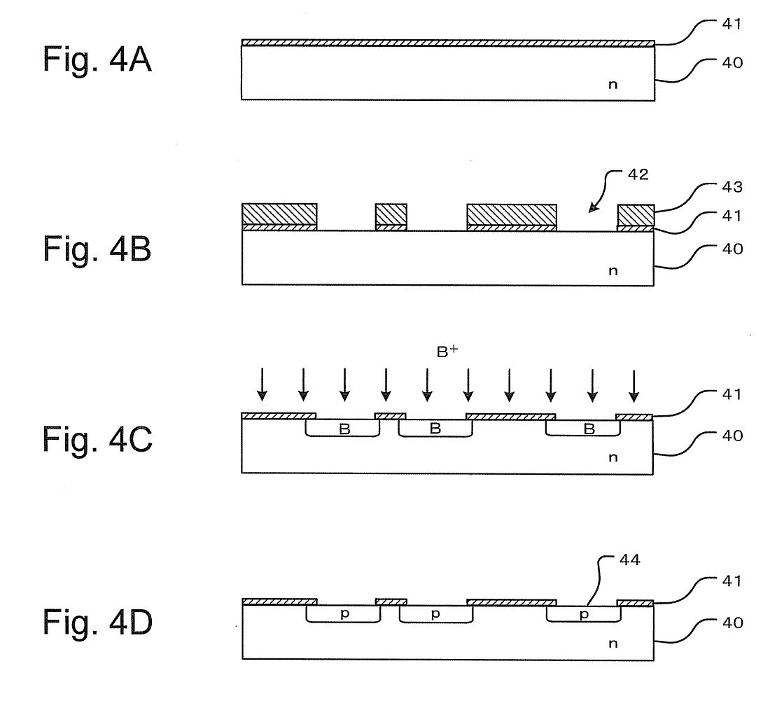

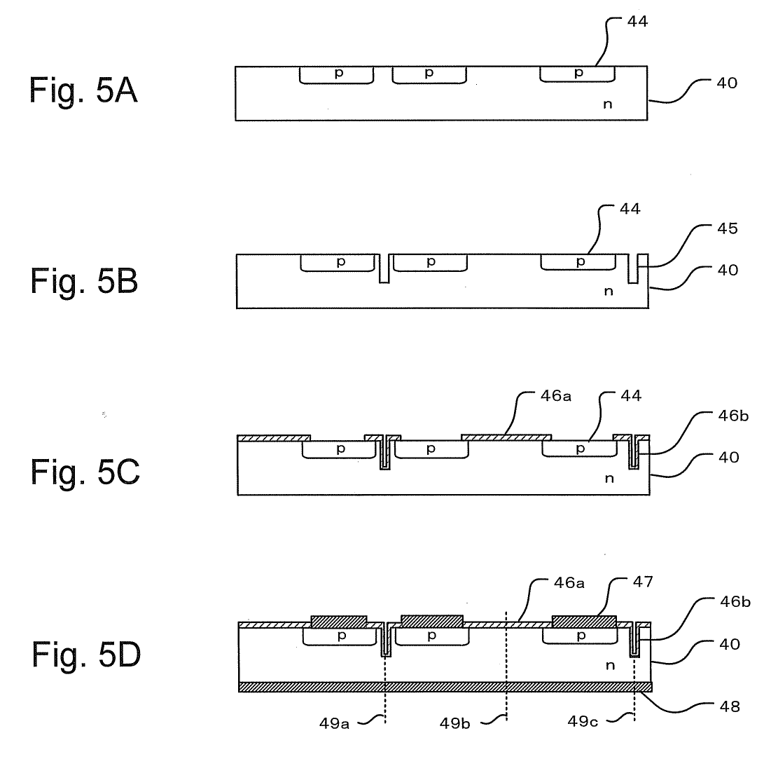

Next, a manufacturing process of the photo receiving element 16 may be explained hereinafter with reference to FIGS. 4A-5D. FIGS. 4A-5D are cross sectional views oft the photo receiving element 16 showing a manufacturing process.

As shown in FIG. 4A, a silicon oxide film 41 is formed on an N type Si substrate 40 by heat oxidation.

As shown in FIG. 4B, a resist layer 43 having an opening 42 is formed on the silicon oxide 41 by lithography. The silicon oxide film 41 is etched by an etchant such as HF with the resist layer 43 as the mask for etching. The Si substrate 40 is exposed from the opening 42.

As shown in FIG. 4C, a P type impurity such as boron (B) ion is implanted into the Si substrate 31 with, for example, accelerating voltage about 300 keV and dose about 5E13 cm⁻².

As shown in FIG. 4D, a P type diffusion layer 44 is obtained by annealing the boron at about 1000 Centigrade.

As shown in FIG. 5A, the silicon oxide 41 is removed.

As shown in FIG. 5B, a trench 45, which is deeper than the P type diffusion layer 44, is formed on the Si substrate 40 by RIE (Reactive Ion Etching). The inner surface of the trench 45 is a photo receiving surface 15. So the inner surface may have low roughness by etching or the like. The width of the trench 45 may be about ten to a hundred micrometers, such that the inner surface of the trench 45 is not damaged by dividing into chips.

As shown in FIG. 5C, silicon oxide layers 46a and 46b are provided on the Si substrate 40, except on the P type diffusion layer 44. The silicon oxide layers 46a and 46b are provided on the inner surface of the trench 45. The silicon oxide layers 46a and 46b are formed by CVD (Chemical Vapor Deposition). In case the thickness of the silicon oxide layers 46a and 46b is (2m+1)λ/(4n), the silicon oxide layers 46a and 46b may function as an anti reflection film.

As shown in FIG. 5D, a P side electrode 47 is formed on the P type diffusion layer 44 and an N side electrode 48 is formed on the bottom surface of the Si substrate 40. The Si substrate 40 is divided into chips by cutting along dicing lines 49a, 49b and 49c. So the photo receiving element 16 as shown in FIGS. 3A and 3B, which has a photo receiving region on its side surface, is obtained.

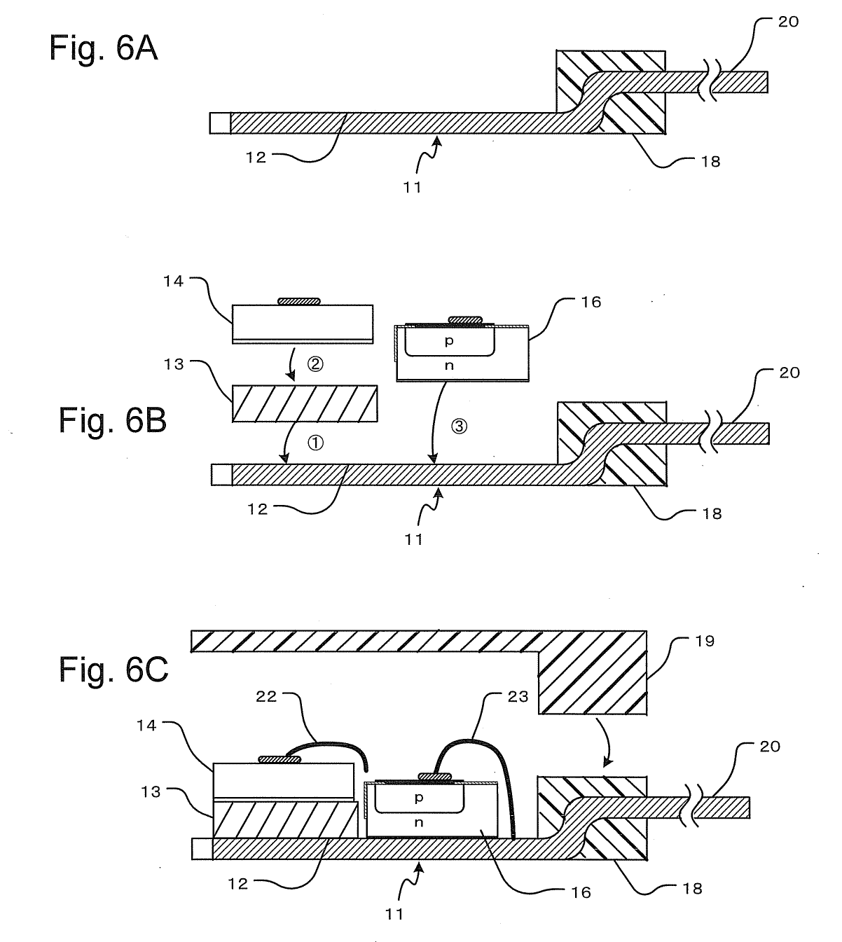

Next, a manufacturing process of the semiconductor laser device 10 will be explained with reference to FIGS. 6A-6C.

As shown in FIG. 6A, an enclosure 18, which is made of a mold resin, is formed on the lead frame 11 with the bottom surface of the lead frame 11 being exposed.

As shown in FIG. 6B, the submount 13 is mounted on the mount bed 12 of the lead frame 11 via, for example, a solder. The semiconductor laser element 14 is mounted on the submount via, for example, an Au—Sn eutectic solder. The semiconductor laser element 14 is mounted as face down or upside down. The photo receiving element 16 is mounted on the mount bed 12 of the lead frame 11 via, for example, a solder with apart from the semiconductor laser element 14.

As shown in FIG. 6C, the semiconductor laser element is connected to the lead pin 20 of the lead frame 11 via the wiring 22. The photo receiving element 16 is connected to the lead pin 20 of the lead frame 11 via the wiring 23. The cap portion 19 is attached on the enclosure 18. So the semiconductor laser device 10 as shown in FIG. 1 is obtained.

In the semiconductor laser device 10 as shown in FIG. 1, a reflection member for reflecting to the receiving region of the photo receiving element may not be necessary, since the monitoring laser is emitted directly to the photo receiving region of the photo receiving element.

The Si substrate 40 may be divided into chips by scribing. In this case, the scattering light may be reflected by the surfaces 31a, 31b, 31c and 31d, since they may be mirror surface. The scattering light into the photo receiving element may be reduced.

A P type diffusion layer, which high impurity concentration boron (B) is implanted into, may be provided on the surfaces 31b, 31c and 31d along the surrounding of the Si substrate 40. The P type diffusion layer may absorb the scattering light from outside from the photo receiving element.

The anti reflection film 34 may be a transparent dielectric, such as a silicon oxide having one fourths wavelength of the monitoring laser in its thickness. The silicon oxide may be formed by plasma CVD or the like.

The P type diffusion layer 44 may be formed a heat diffusion.

The Si substrate 40 may be an N type substrate and the diffusion layer may be the opposite conductive, P type diffusion layer.

### Second Embodiment

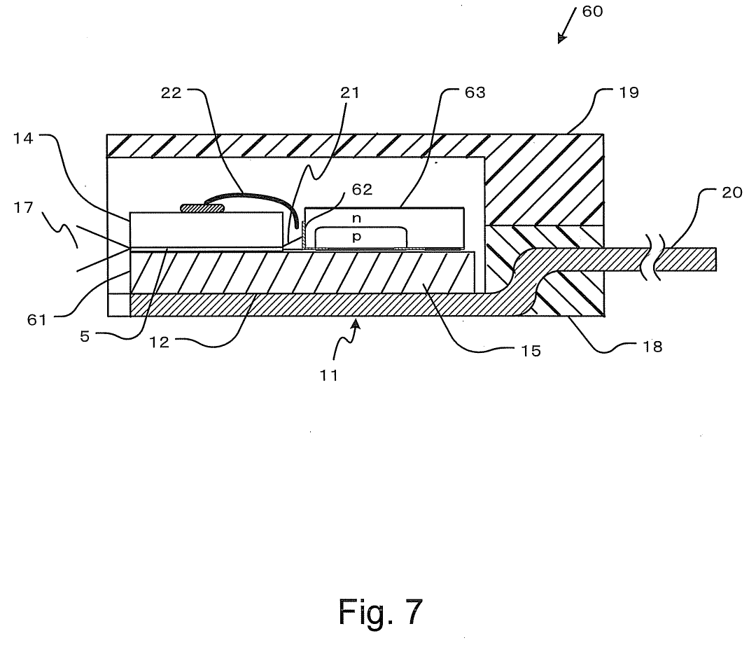

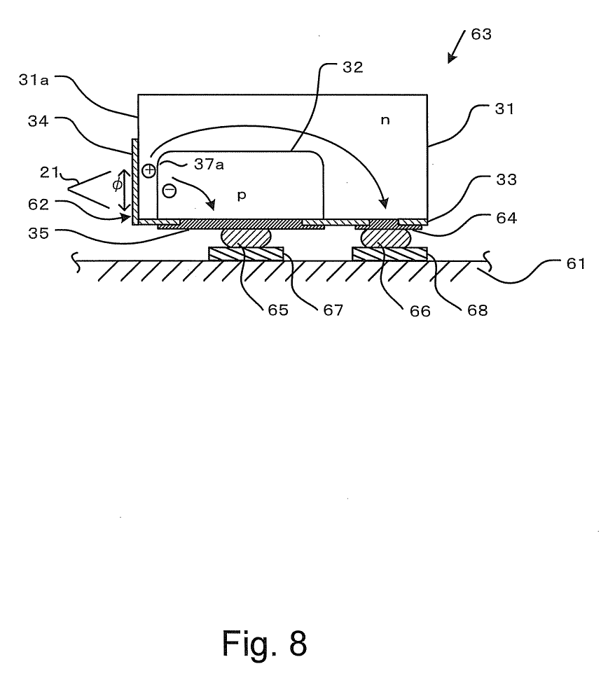

A second embodiment is explained with reference to FIGS. 7 and 8.

A semiconductor laser device 81 is described in accordance with a second embodiment. FIG. 7 is a cross sectional view of a semiconductor laser device 60 in accordance with a second embodiment. In this second embodiment, the photo receiving element is mounted as flip chip mount. FIG. 8 is a cross sectional view of a photo receiving element 63 in accordance with the second embodiment.

As shown in FIG. 7, in the semiconductor laser device 60, the semiconductor laser element 14 is mounted on a submount 61 as face down. The photo receiving element 63 is mounted on the submount 61 with being apart form the rear side of the semiconductor laser element 14. The structure of the photo receiving element 63 is the same as the photo receiving element 16 as explained in the first embodiment. The receiving region 62 of the photo receiving element 63 faces the rear side of the semiconductor laser element 14. The submount 61 is mounted on the mount bed 12 of the lead frame 11.

The laser beam 21 irradiated on the photo receiving element 63 is provided in the receiving region 62. The height from the top surface of the submount to the upper edge of the receiving region 62 is greater than the height from the top surface of the submount to the upper edge of the laser beam irradiated on the photo receiving element 63.

As shown in FIG. 8, a P side electrode 35 and an N side electrode 64 are provided on the top surface (lower in FIG. 8) of the photo receiving element 63. The photo receiving element 63 is mounted on the submount 61 via Au bumps 65 and 66. The bumps 65 and 66 are provided on wirings 67 and 68, respectively.

In this embodiment, the wiring from the photo receiving element to the lead pin 20 is not necessary. So the possibility of the cutting the wiring may be reduced.

### Third Embodiment

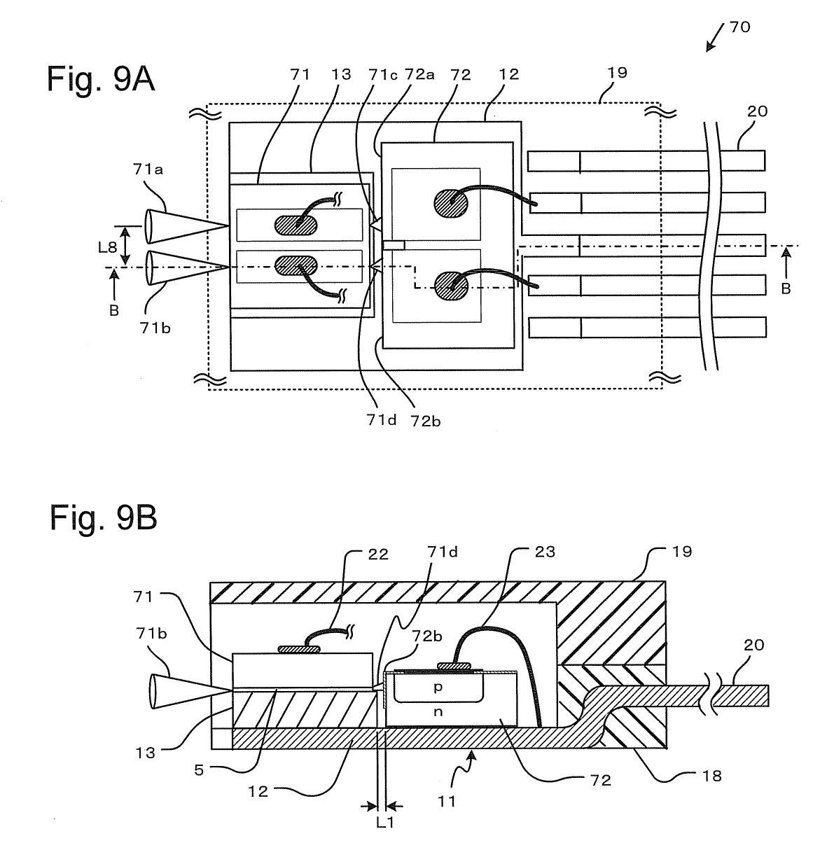

A third embodiment is explained with reference to FIGS. 9-11A.

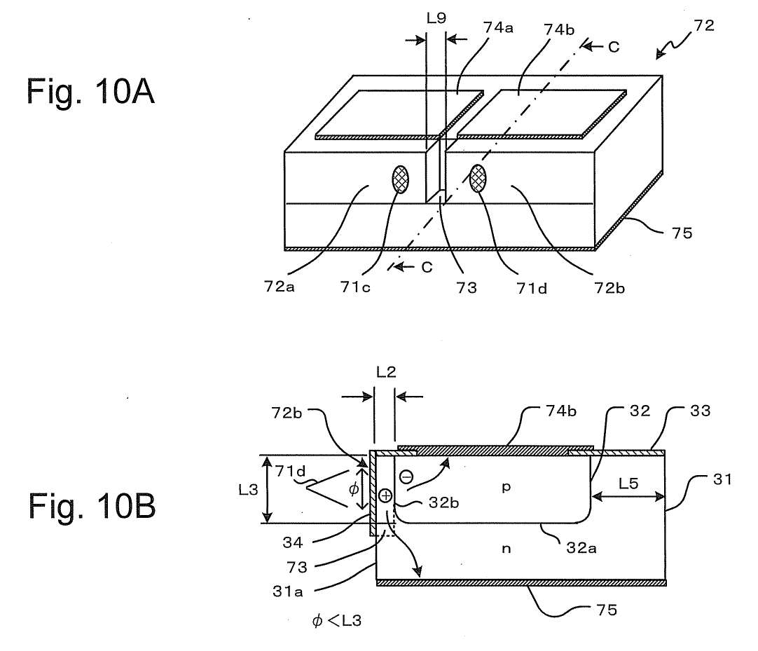

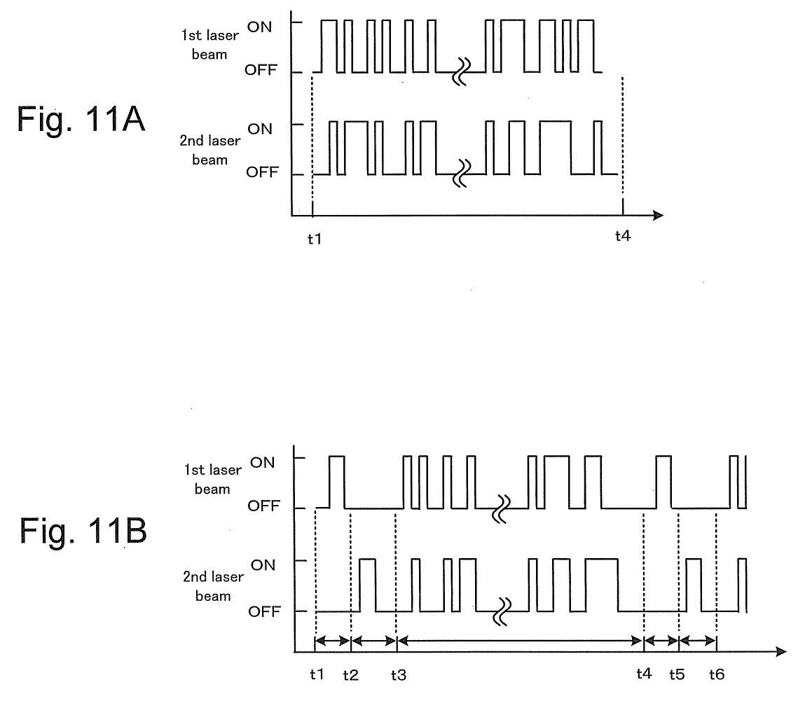

A semiconductor laser device 70 is described in accordance with a third embodiment. FIG. 9A is a plane view of the semiconductor laser device 70 in accordance with the third embodiment. FIG. 9B is a cross sectional view of the semiconductor laser device 70 in accordance with the third embodiment. FIG. 10A is a perspective view of a photo receiving element 72 in accordance with the third embodiment. FIG. 10B is a cross sectional view of the photo receiving element 72 in accordance with the third embodiment. FIG. 11A is a timing of the semiconductor laser device in accordance with the third embodiment. FIG. 11B is a timing of the semiconductor laser device in accordance with a comparative example.

In this third embodiment, the semiconductor laser element 71 is configured to emit two lasers and the photo receiving element 72 has two photo receiving region.

As shown in FIG. 9A and 9B, the semiconductor laser device 70 has a semiconductor laser element 71 and the photo receiving element 72. The semiconductor laser element 71 is configured to emit a first laser 71a and a second laser 71b from the front surface of the semiconductor laser element 71, and configured to emit a first monitoring laser 71c and a second monitoring laser 71d from the rear surface of the semiconductor laser element 71. The photo receiving element 72 is configured to receive the first monitoring laser 71c by the first photo receiving region 72a and to receive the second monitoring laser 71d by the second photo receiving region 72b.

The semiconductor laser element 71 may be AlGaAs based semiconductor laser and configured to emit 790 nm lasers in their wavelength.

The distance L8, which is from the emission center of the first laser 71a to the emission center of the second laser 71b, may be about 10-100 micrometers. The areas of the receiving regions 72a and 72b may be about 10 micrometers square to some hundred meters square. The trench 73 may be formed RIE, wet etching or the like.

In case the half angles in the lateral plane of the first and second monitoring lasers 71c and 72d are about 10 degree and the distance L1 is 300 micrometers, the first monitoring laser 71c is irradiated on the photo receiving region 72a and the second monitoring laser 71d is irradiated on the photo receiving region 72b.

The first laser 71a and the second laser 72 may be controlled independently.

In case the semiconductor laser device 70 is used writing device in a copier or a laser beam printer, the first laser 71a and the second laser 72 may be operated by APC (Automatic Power Control) at the same time. The first laser 71a and the second laser 72 may be operated by APC during one of them writing data.

As shown in FIGS. 10A, a trench 73 is provided between the photo receiving region 72a and 72b in the photo receiving element 72. The distance from the photo receiving region 72a to the photo receiving region 72b may be substantially equal to the distance L8.

The photo receiving regions 72a and 72b are electrically separated by the trench 73. The trench 73 has its depth L3 and its width L2. The bottom of the trench 73 is provided lower than the lower edge of the PN junction 32a. The inner edge of the trench 73 is provided more inward from the font surface of the photo receiving element 72 than the PN junction 32b.

The photo receiving element 72 may be formed as shown in FIGS. 4-5 and formed opening pattern corresponding to the distance L9, which is the width of the trench 73, such as 5 micrometers.

The operation of the semiconductor laser device 70 in accordance with this embodiment will be explained with reference to the timing chart. The operation is explained with comparing to a comparative example.

First the comparative example is explained. In the comparative example, the semiconductor laser element is configured to emit two lasers and the photo receiving element has single photo receiving region.

As shown in FIG. 11B, in the comparative example, the photo receiving element is not capable of receive the two lasers at the same time. The photo receiving element is capable of receive only one of the two lasers.

So it is necessary that the semiconductor laser element is controlled by APC with one of the lasers being ON and the other is OFF, such that a stable optical output from the semiconductor laser device is obtained.

During the time t1-t2, the first laser is ON, and the second laser is OFF. The first monitoring laser is received by the photo receiving element, and the driving current of the semiconductor laser is controlled so as to obtain a stable optical output as first laser beam.

During the time t2-t3, the second laser is ON, and the first laser is OFF. The second monitoring laser is received by the photo receiving element, and the driving current of the semiconductor laser is controlled so as to obtain a stable optical output as second laser beam.

During the time t3-t4, the data is capable of being written to the laser beam printer at the double speed by the first laser and the second laser.

After the time t4, the above operation is repeated. When the semiconductor laser device is operated in constant current, the optical output from the first and the second laser may be unstable by the heat generated from the semiconductor laser element. So the semiconductor laser device is operated intermittently by the APC with not being over the acceptable range of optical output, and the data is written.

On the other hand, as shown in FIG. 11A, the photo receiving element is capable of receiving the first and second monitoring laser at the same time. So the first laser and the second laser are capable of being controlled by the APC independently. So the time for writing data may be reduced. So the semiconductor laser device which is capable of being operated fast may be obtained.

The semiconductor laser element may be configured to more than two lasers and the photo receiving element is configured to receive the more than two lasers.

The wavelength of the plurality of lasers may be different to each other.

A surface of the trench 73 may be roughened by alkaline etchant, so that monitoring laser irradiated in the trench 73 is scattered. A layer, which is capable of absorb the monitoring laser, such as black insulative resin, may be provided on the trench 73. So the monitoring laser irradiated to the trench 73 hardly reaches the PN junction in the photo receiving element. So S/N ratio may be improved.

### Fourth Embodiment

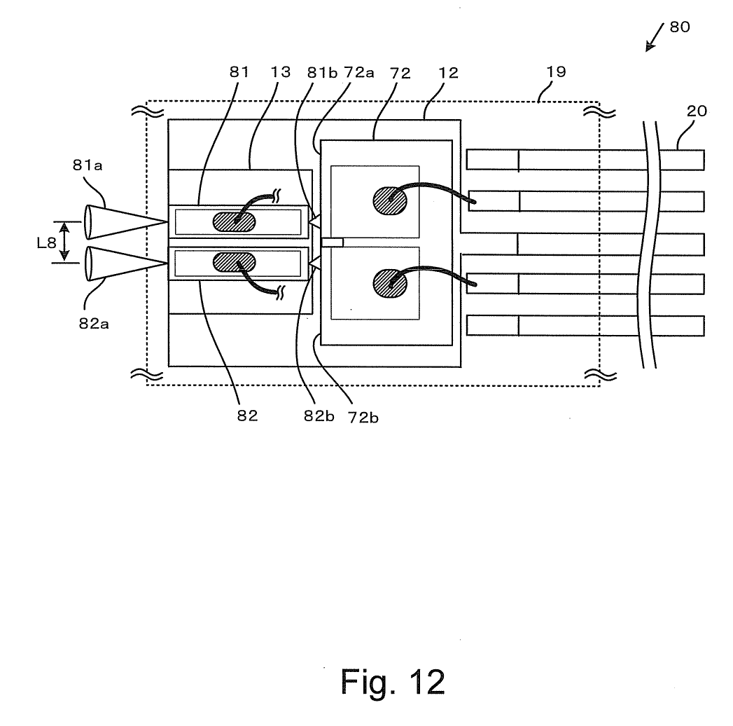

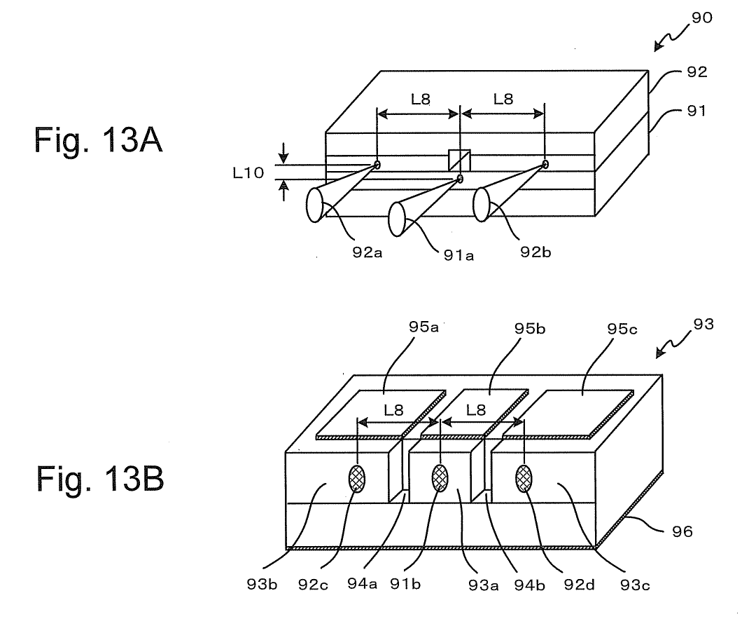

A fourth embodiment is explained with reference to FIGS. 12-13B

A semiconductor laser device 80 is described in accordance with a fourth embodiment.

In this fourth embodiment, a plurality of semiconductor laser elements and a photo receiving element having a plurality of photo receiving regions are provided.

As shown in FIG. 12, a first semiconductor laser element 81 is configured to emit a first laser 81a from the front surface and emit a first monitoring laser 81b from the rear surface. A second semiconductor laser element 82 is configured to emit a second laser 82a from the front surface and emit a second monitoring laser 82b from the rear surface. The semiconductor laser elements 81 and 82 axe provided on the submount 13 with parallel to each other.

The photo receiving element 72 has a photo receiving region 72a and 72b. The monitoring laser 81b, is irradiated to the photo receiving region 72a. The monitoring laser 82b is irradiated to the photo receiving region 72b.

The wavelength of the first laser 81a and the second laser 82a may be same or different. For example, the first semiconductor laser element 81 and the second semiconductor laser element 82 are made of AlGaAs based semiconductors and configured to emit 790 nm wavelength lasers. The first semiconductor laser element 81 is made of AlInGaAlP based semiconductors and configured to emit 650 nm wavelength, and the second semiconductor laser 82 is made of AlGaAs based semiconductor and emit 790 nm wavelength laser.

The photo receiving element 72 may be made of a Si photo diode and having a receiving sensitivity in 650 nm and 780 nm.

As mentioned above, a plurality of the semiconductor laser elements may be provided instead of the semiconductor laser element emitting a plurality of lasers.

As shown in FIGS. 13A and 13B, the laser from the semiconductor laser element is not on a single line.

FIG. 13A is a perspective view of a semiconductor laser element 90 in accordance with a modification of the fourth embodiment. FIG. 13B is a perspective view of a photo receiving element 93 in accordance with the modification of the fourth embodiment.

IN the semiconductor laser element 90, a first semiconductor laser element 91 and a second semiconductor laser element 92 are provided. The second semiconductor laser element 92 is mounted on the first semiconductor laser element 91 as face down. The first semiconductor laser element 91 is mounted on the submount (not shown n FIG. 13A) as face up.

The first semiconductor laser element 91 may be made of InGaAlN based semiconductors and configured to emit blue violet laser. The second semiconductor laser element 92 may be made of AlInGaP based semiconductors and configured to emit two lasers.

The first semiconductor laser element 91 is configured to emit laser 91a. The second semiconductor laser element 92 is configured to emit laser 92a and 92b. The lasers 91a, 92a and 92b are parallel. The first semiconductor laser element 91 and the second semiconductor laser element 92 are configured to emit monitoring lasers (not shown in FIG. 13A and 13B).

The distance from the first laser beam 91a to the second laser beam 92a and the distance from the first laser beam 91a to the second laser beam 92b are same. The distance L8 may be 100 micrometers.

The vertical distance L 10 from the first laser beam to the second and third laser beams may be about no more than 10 micrometers, since the first semiconductor laser 92 is mounted as face down on face up mounted the first semiconductor laser 91. So the irradiated laser beams on the photo receiving element may be regarded as the irradiated laser beams being on a single line.

The photo receiving element 93 has three photo receiving regions 93a, 93b and 93c. A first monitoring laser beam 91b is irradiated on the first receiving region 93a, the second monitoring laser beam 92c is irradiated on the second receiving region 93b, and the third monitoring laser beam 92d is irradiated on the third receiving region 93c.

The photo receiving regions 93a, 93b and 93c are separated by a trench 94a and 94b.

### Fifth Embodiment

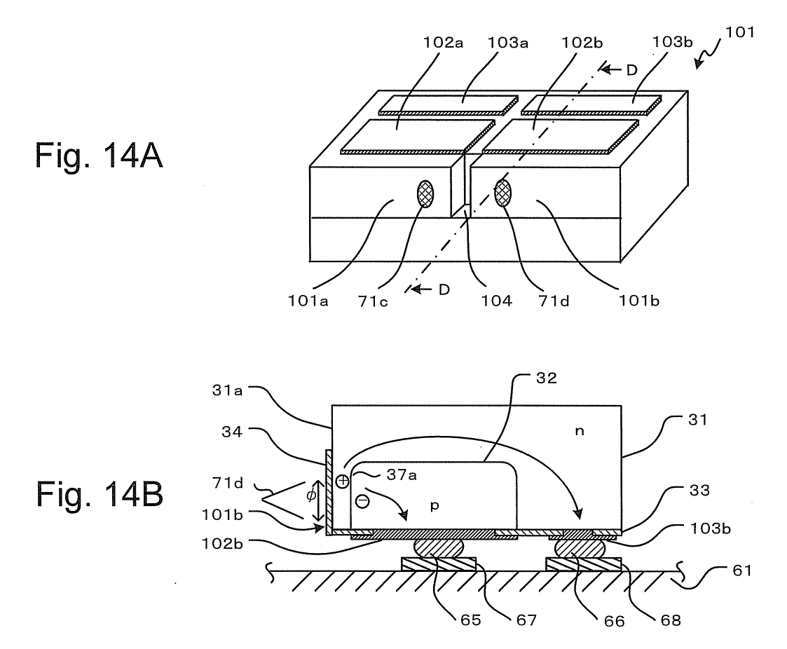

A fifth embodiment is explained with reference to FIG. 14.

A semiconductor laser device is described in accordance with a fifth embodiment. FIG. 14A is a perspective view of a photo receiving element 101 in accordance with a fifth embodiment. FIG. 14B is a cross sectional view of the photo receiving element 101 in accordance with a fifth embodiment.

In this fifth embodiment, the photo receiving element having a plurality of photo receiving regions is mounted on the submount 61 as flip chip (face down).

As shown in FIG. 14A, the photo receiving element 101 has a first photo receiving region 101a and a second photo receiving region 101b. The first photo receiving region 101a and a second photo receiving region 101b are separated by a trench 104. P side electrodes and N side electrodes are provided on a top surface of the photo receiving element 101.

A P side electrode 102a and an N side electrode 103a are provided for the photo receiving region 101a. A P side electrode 102b and an N side electrode 103b are provided for the second photo receiving region 101b.

As shown in FIG. 14B, the P side electrodes 102a and 102b are electrically connected to a wiring 67 provided on the insulative submount 61 via a bump 65. The N side electrode 103a and 103b are electrically connected to a wiring 68 provided on the insulative submount 61 via a bump 66.

In case the semiconductor laser element 71 and photo receiving element 101 are provided on the submount, the height from the submount to the laser emission region is capable of the same height from the submount to the photo receiving region.

Embodiments of the invention have been described with reference to the examples. However, the invention is not limited thereto.

For example, the material of the semiconductor laser chip is not limited to InGaAlP-based or GaN-based semiconductors, but may include various other Group III-V compound semiconductors such as GaAlAs-based and InP-based semiconductors, or Group II-VI compound semiconductors, or various other semiconductors.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor laser device, comprising:
a supporting member;
a semiconductor laser element provided over the supporting member, and configured to emit a laser from a front surface and monitoring laser from a rear surface; and
a photo receiving element provided over the supporting member, and configured to receive the monitoring laser from the semiconductor laser element at a photo receiving region, the photo receiving region provided on a side surface of the photo receiving element;
wherein the side surface of the photo receiving element has a smaller area than an area of a bottom surface of the photo receiving element.

2. A semiconductor laser device, comprising:
a supporting member;
a semiconductor laser element provided over the supporting member, and configured to emit a plurality of lasers from a front surface and a plurality of monitoring lasers from a rear surface; and
a photo receiving element provided over the supporting member, and configured to receive the plurality of monitoring lasers from the semiconductor laser element at a plurality of photo receiving regions respectively, each of the plurality of photo receiving regions provided on a side surface of the photo receiving element;
wherein the side surface of the photo receiving element has a smaller area than an area of a bottom surface of the photo receiving element, and the photo receiving element is spaced from the semiconductor laser element so that the plurality of the monitoring lasers does not cross each other.

3. A semiconductor laser device, comprising:
a supporting member;
a plurality of semiconductor laser elements provided over the supporting member, each semiconductor laser element configured to emit a laser from a front surface and a monitoring laser from a rear surface, respectively; and
a photo receiving element provided over the supporting member, and configured to receive the plurality of monitoring lasers from the plurality of semiconductor laser elements at a plurality of photo receiving regions respectively, the plurality of photo receiving regions provided on a side surface of the photo receiving element;
wherein the side surface of the photo receiving element has a smaller area than an area of a bottom surface of the photo receiving element, and the photo receiving element is spaced from the plurality of the semiconductor laser elements so that the plurality of the monitoring lasers does not cross each other.

4. A semiconductor laser device of claim 1, wherein a height from the supporting member to an active layer of the semiconductor laser elements is at least one of greater than and equal to a height from the supporting member to a bottom of the photo receiving region and at least one of less than and equal to a height from the supporting member to a top of the photo receiving region.

5. A semiconductor laser device of claim 2, wherein a height from the supporting member to an active layer of the semiconductor laser elements is at least one of greater than and equal to a height from the supporting member to a bottom of the photo receiving region and at least one of less than and equal to a height from the supporting member to a top of the photo receiving region.

6. A semiconductor laser device of claim 3, wherein a height from the supporting member to an active layer of the semiconductor laser elements is at least one of greater than and equal to a height from the supporting member to a bottom of the photo receiving region and at least one of less than and equal to a height from the supporting member to a top of the photo receiving region.

7. A semiconductor laser device of claim 1, wherein a distance from a side surface having the photo receiving region to a front edge of a PN junction in the photo receiving element is at least one of less than and equal to a distance from another side surface of the photo receiving element to the PN junction in the photo receiving element.

8. A semiconductor laser device of claim 2, wherein a distance from a side surface having the photo receiving region to a front edge of a PN junction in the photo receiving element is at least one of less than and equal to a distance from another side surface of the photo receiving element to the PN junction in the photo receiving element.

9. A semiconductor laser device of claim 3, wherein a distance from a side surface having the photo receiving region to a front edge of a PN junction in the photo receiving element is at least one of less than and equal to a distance from another side surface of the photo receiving element to the PN junction in the photo receiving element.

10. A semiconductor laser device of claim 1, wherein an anti reflection film is provided on the photo receiving region.

11. A semiconductor laser device of claim 2, wherein an anti reflection film is provided on the photo receiving region.

12. A semiconductor laser device of claim 3, wherein an anti reflection film is provided on the photo receiving region.

13. A semiconductor laser device of claim 1, wherein the photo receiving element is positioned to directly receive the monitoring laser.

14. A semiconductor laser device of claim 2, wherein the photo receiving element is positioned to directly receive the monitoring laser.

15. A semiconductor laser device of claim 3, wherein the photo receiving element is positioned to directly receive the monitoring laser.

16. A semiconductor laser device of claim 1, wherein a side surface of the photo receiving element has a smaller area than an area of a bottom surface of the photo receiving element.

17. A semiconductor laser device of claim 2, wherein a side surface of the photo receiving element has a smaller area than an area of a bottom surface of the photo receiving element.

18. A semiconductor laser device of claim 3, wherein a side surface of the photo receiving element has a smaller area than an area of a bottom surface of the photo receiving element.
